(19) United States
(12) Patent Application Publication
(10) Pub. No.: US 2015/0243346 A1
(43) Pub. Date: Aug. 27, 2015

(54) SEMICONDUCTOR DEVICE HAVING HIERARCHICALLY STRUCTURED WORD LINES

(71) Applicants: Munetoshi OHATA, (US); Sachiko EDO, (US); Gen KOSHITA, (US); PS4 LUXCO S.A.R.L., Luxembourg (LU)

(72) Inventors: Munetoshi Ohata, Tokyo (JP); Sachiko Edo, Tokyo (JP); Gen Koshita, Tokyo (JP)

(73) Assignee: PS4 LUXCO S.A.R.L., Luxembourg (LU)

(21) Appl. No.: 14/429,760

(22) PCT Filed: Sep. 20, 2013
(86) PCT No.: PCT/JP2013/005569

§ 371 Date: Mar. 19, 2015

(30) Foreign Application Priority Data
Sep. 26, 2012 (JP) 2012-212736

(51) Int. Cl. G11C 11/408; G11C 11/4074; G11C 11/4097

(52) U.S. Cl. CPC G11C 11/4085; G11C 11/4087; G11C 11/4097; G11C 11/4074

(57) ABSTRACT

Disclosed herein is a semiconductor device that includes: a memory cell array including sub-word lines, bit lines and memory cells arranged at intersections of the sub-word lines and the bit lines; a plurality of sub-word drivers each drives an associated one of the sub-word lines; and a plurality of main word drivers each supplies a main word signal having one of a selected-level potential and an unselected-level potential to an associated one of the sub-word drivers. Each of the sub-word drivers drives the associated one of the sub-word lines to an active level when an associated one of the main word signals has the selected-level potential, and drives the associated one of the sub-word lines to an inactive level when the associated one of the main word signals has the unselected-level potential. The unselected-level potential of the main word signals is variable depending on an operation mode.

### BACKGROUND

1. Field of the Invention

The present invention relates to a semiconductor device, and more particularly relates to a semiconductor device that includes main word drivers and sub-word drivers.

2. Description of Related Art

In a DRAM (Dynamic Random Access Memory) that is one of typical semi-conductor devices, word lines are hierarchically structured into main word lines and sub-word lines (see Japanese Patent Application Laid-open No. 2005-135461). The main word lines are activated by main word drivers and the sub-word lines are activated by sub-word drivers. Because a general sub-word driver is similar in circuit configuration to a CMOS inverter, a low level of an input signal to the sub-word driver, that is, the low level of a main word signal corresponds to a selected level and a high level thereof corresponds to an unselected level.

Furthermore, a general DRAM uses a boost potential that is higher than an external power-supply potential supplied from outside as an active-level potential of the sub-word lines. Therefore, the general DRAM similarly uses the boost potential as an un-selected-level potential of the main word signals.

However, in a period in which the main word signals are maintained to have the un-selected-level potential (the boost potential), a leak current referred to as “GIDL (Gate Induced Drain Leak)” flows in the sub-word drivers. The GIDL is a leak current that flows from a well to a drain of a transistor when the gate-drain voltage of the transistor becomes higher, and the GIDL is mainly generated in a P-channel MOS transistor included in the sub-word drivers. The GIDL per transistor is very low, for example, in the order of nA (nanoamperes). However, the GIDL generated in the entire chip is, for example, in the order of mA (milliamperes) because many sub-word drivers are included in a memory cell array. Accordingly, the leakage amount of the GIDL is not negligible at the time of a standby state, particularly at the time of a self-refresh mode at which the reduction in current consumption is required.

### SUMMARY

In one embodiment, there is provided a semiconductor device that includes: a memory cell array including a plurality of sub-word lines, a plurality of bit lines and a plurality of memory cells arranged at intersections of the sub-word lines and the bit lines; a plurality of sub-word drivers each drives an associated one of the sub-word lines; and a plurality of main word drivers each supplies a main word signal having one of a selected-level potential and an unselected-level potential to an associated one of the sub-word drivers. Each of the sub-word drivers drives the associated one of the sub-word lines to an active level when an associated one of the main word signals has the selected-level potential, and drives the associated one of the sub-word lines to an inactive level when the associated one of the main word signals has the unselected-level potential. The unselected-level potential of the main word signals is variable depending on an operation mode.

In another embodiment, there is provided a semiconductor device that includes: a sub-word selection driver generating a sub-word selection signal having one of an active-level potential and an inactive-level potential based on an address signal; a main word driver generating a main word signal having one of a selected-level potential and an unselected-level potential based on the address signal; a sub-word driver activates a sub-word line when the sub-word selection signal has the active-level potential and the main word signal has the selected-level potential; and a power-supply circuit that generates the unselected-level potential by selecting one of a plurality of potentials including at least first and second potentials based on a control signal.

In still another embodiment, there is provided a semiconductor device that includes: a first decoder that generates a first selection signal by decoding a first part of an address signal; a second decoder that generates a second selection signal by decoding a second part of the address signal; a sub-word selection driver that includes first and second transistors that are connected in series, the first selection signal being supplied to gate electrodes of the first and second transistors; a main word driver that includes third and fourth transistors that are connected in series, the second selection signal being supplied to gate electrodes of the third and fourth transistors; a sub-word driver that includes fifth and sixth transistors that are connected in series, drains of the fifth and sixth transistors being connected to a sub-word line, a source of the fifth transistor being connected to drains of the first and second transistors, gate electrodes of the fifth and sixth transistors being connected to drains of the third and fourth transistors; and a power-supply circuit that supplies a first potential to sources of the first and third transistors in a first operation mode, and supplies a second potential that is lower than the first potential to at least the source of the third transistor in a second operation mode.

According to the present invention, it is possible to reduce the GIDL generated in a sub-word driver at the time of, for example, a standby state because an unselected-level potential of a main word signal is variable.

### BRIEF DESCRIPTION OF DRAWINGS

FIG. 1 is a block diagram showing a configuration of a semiconductor device 100 according to a first embodiment of the present invention;

FIG. 2 is a schematic diagram for explaining the configuration of the memory cell array 101;

FIG. 3 is a circuit diagram of the main word driver MWD;

FIG. 4 is a circuit diagram of the sub-word selection driver FXD;

FIG. 5 is a circuit diagram of the sub-word driver SWD;

FIG. 6 is a timing diagram for explaining an operation at the time of row access;

FIG. 7 is a circuit diagram for explaining a connection relation among the main word driver MWD, the sub-word selection driver FXD, and the sub-word driver SWD;

FIG. 8 is a circuit diagram of the boost-potential generation circuit 170;

FIG. 9 is a waveform diagram for explaining an operation of the boost-potential generation circuit 170;

FIG. 10 is a graph showing a relation between the gate-drain voltage Vgd and the GIDL;

FIG. 11 is a circuit diagram of a boost-potential generation circuit 170a according to a modification of the first embodiment;

FIG. 12 is a waveform diagram for explaining an operation of the boost-potential generation circuit 170a;

FIG. 13 is a block diagram showing a configuration of a semiconductor device 200 according to a second embodiment of the present invention;

FIG. 14 is a waveform diagram for explaining an operation of the boost-potential generation circuit 270;

FIG. 15 is a circuit diagram for explaining supply destinations of the boost potentials Vw and Vw2;

FIG. 16 is a block diagram showing a configuration of a semiconductor device 300 according to a third embodiment of the present invention;

FIG. 17 is a circuit diagram of a switching circuit 310 that supplies a source potential to the buffer circuit unit 142 of the main word driver MWD;

FIG. 18 is a timing diagram for explaining an operation performed by the semi-conductor device 300 according to the third embodiment;

FIG. 19 is a circuit diagram for explaining supply destinations of the boost potentials Vw and Vw2;

FIG. 20 is a circuit diagram of a switching circuit 310a according to a modification of the third embodiment; and

FIG. 21 is a timing diagram for explaining an operation performed by the semi-conductor device 300 in a case of using the switching circuit 310a according to the modification of the third embodiment.

### DESCRIPTION OF EMBODIMENTS

Preferred embodiments of the present invention will be explained below in detail with reference to the accompanying drawings.

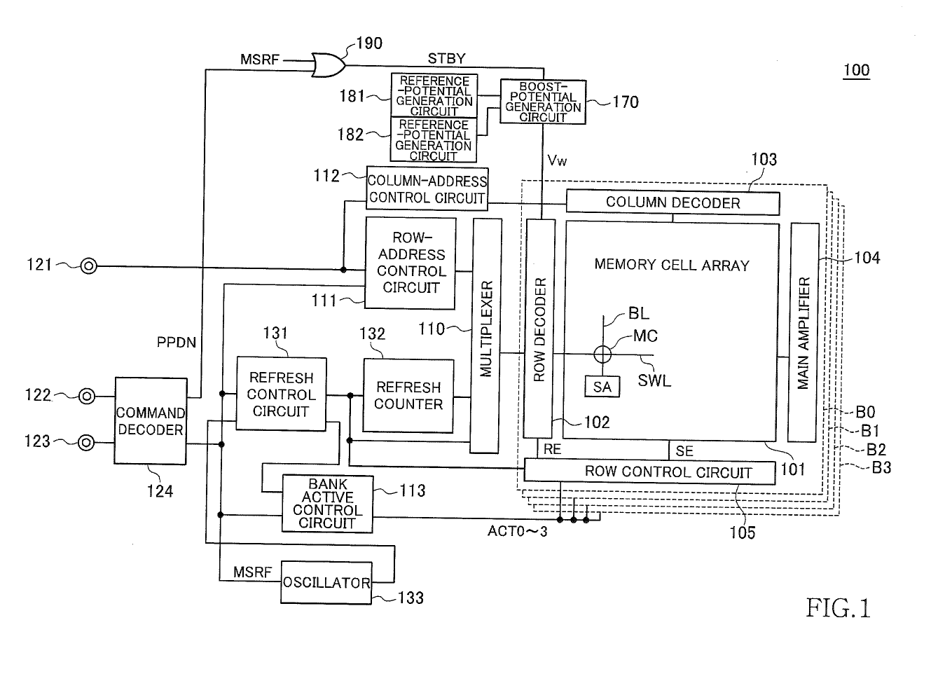

Referring now to FIG. 1, the semiconductor device 100 according to the first embodiment of the present invention is a DRAM and includes four memory banks B0 to B3. The memory banks B0 to B3 are units capable of executing commands in a non-exclusive manner. Each of the memory banks includes a memory cell array 101, a row decoder 102, a column decoder 103, a main amplifier 104, and a row control circuit 105. The memory cell array 101 includes a plurality of sub-word lines SWL, a plurality of bit lines BL, and a plurality of memory cells MC respectively arranged at intersections between the sub-word lines SWL and the bit lines BL. A configuration of the memory cell array 101 is described later.

As shown in FIG. 1, address pins 121, bank address pins 122, and command pins 123 that are external terminals are provided on the semiconductor device 100 according to the first embodiment. Although data pins, power supply pins, and the like are also provided on the semiconductor device 100, these pins are not shown in FIG. 1. The address pins 121 are supplied with address signal. The address signals supplied to the address pins 121 are transferred to a row-address control circuit 111 or a column-address control circuit 112. Furthermore, the bank address pins 122 and the command pins 123 are supplied with bank address signal and command signal, respectively.

A command decoder 124 decodes the command signal and generates various internal signals based on a decoding result.

For example, when the command signal indicates an active command, the command decoder 124 generates an active signal. The active signal is supplied to the row-address control circuit 111 and a bank active control circuit 113. The bank active control circuit 113 activates corresponding one of bank active signals ACT0 to ACT3 based on the bank address input via the bank address pins 122. In this manner, one of the memory banks B0 to B3 is selected at the time of row access. Furthermore, by activation of the active signal, the address signal input via the address pin 121 is supplied to the row-address control circuit 111. The address signal supplied to the row-address control circuit 111 is transferred to the row decoder 102 via a multiplexer 110, thereby selecting one of the sub-word lines SWL. An operation timing of the row decoder 102 is specified by a row enable signal RE output from the row control circuit 105. Furthermore, when a predetermined time elapses after the sub-word line SWL is activated, the row control circuit 105 activates a sense enable signal SE, thereby activating one of sense amplifiers SA included in the memory cell array 101.

When the command signal indicates an auto-refresh command, the command decoder 124 generates a refresh signal. A refresh control circuit 131 is thereby activated and an address signal held in a refresh counter 132 is supplied to the row decoder 102 via the multiplexer 110. A refresh operation is thereby performed on the memory cells MC connected to a predetermined sub-word line SWL.

When the command signal indicates a self-refresh command, the command decoder 124 generates a self-refresh signal MSRF. When the command decoder 124 activates the self-refresh signal MSRF, an oscillator 133 is activated and refresh signals are generated automatically and periodically. The refresh operation is thereby performed on the memory cells MC automatically and periodically. Such an operation mode is a type of a standby state referred to as “self-refresh mode” and current consumption is greatly reduced in the self-refresh mode.

When the command signal indicates a precharge power-down command, the command decoder 124 generates a precharge power-down signal PPDN. The operation mode thereby enters a low current consumption state while all the memory banks B0 to B3 are made in a precharged state. Such an operation mode is a type of a standby state referred to as “precharge power-down mode” and the current consumption is reduced in the precharge power-down mode.

Furthermore, when the command signal indicates a read command or a write command, the command decoder 124 generates a column signal. After the column signal is generated, the address signal input via the address pins 121 is transferred to the column-address control circuit 112. The address signal supplied to the column-address control circuit 112 is transferred to the column decoder 103, thereby selecting one of the bit lines BL. As a result, when the command signal indicates the read command, read data read from the memory cell array 101 is amplified via the main amplifier 104 and output to outside. On the other hand, when the command signal indicates the write command, write data supplied from outside is written to the memory cell array 101 via the main amplifier 104.

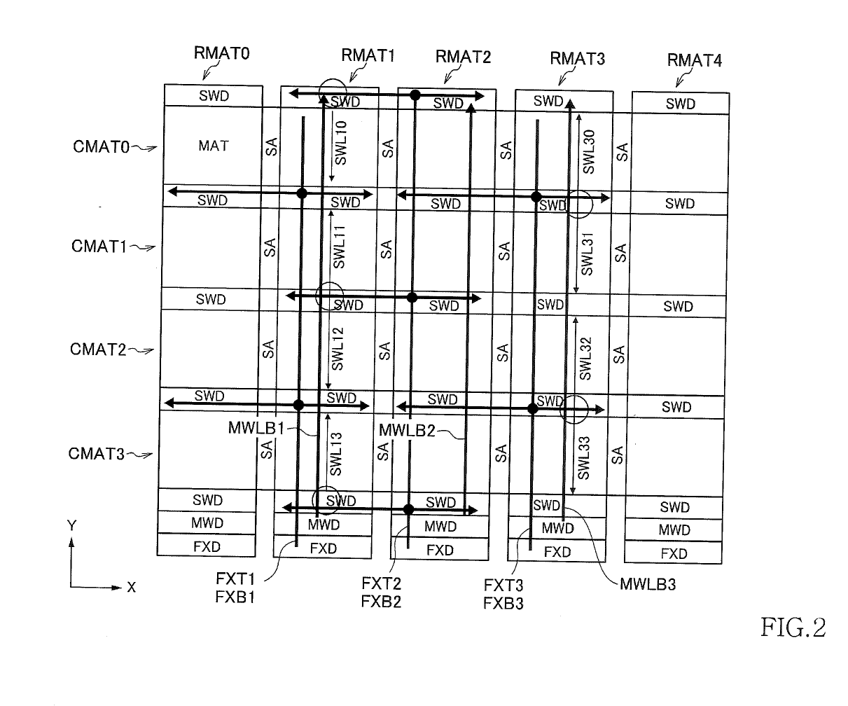

Turning to FIG. 2, a plurality of memory mats MAT are laid out in a matrix in the memory cell array 101. A sub-word driver SWD is arranged between the two memory mats MAT adjacent to each other in a Y-direction and each of the sense amplifiers SA is arranged between the two memory mats MAT adjacent to each other in an X-direction. The sub-word driver SWD is a circuit that drives the corresponding sub-word line SWL and the sense amplifier SA is a circuit that amplifies a potential difference between a pair of corresponding bit lines BL.

The sub-word driver SWD operates under control of one main word signal MWLB and sub-word selection signals FX. The main word signal MWLB is a signal generated by a main word driver MWD that is a part of the row decoder 102 and each main word signal MWLB is allocated to a corresponding memory mat array RMAT. For example, a main word signal MWLB1 is allocated to a memory mat array RMAT1, a main word signal MWLB2 is allocated to a memory mat array RMAT2, and a main word signal MWLB3 is allocated to a memory mat array RMAT3. Meanwhile, the sub-word selection signals FX are signals generated by a sub-word selection driver FXD that is a part of the row decoder 102 and each of the sub-word selection signals FX is allocated to the two memory mat areas RMAT. For example, complementary sub-word selection signals FXT1 and FXB1 are allocated to memory mat areas RMAT0 and RMAT1, complementary sub-word selection signals FXT2 and FXB2 are allocated to the memory mat areas RMAT1 and RMAT2, and complementary sub-word selection signals FXT3 and FXB3 are allocated to the memory mat areas RMAT2 and RMAT3.

Circles shown in FIG. 2 denote the sub-word drivers SWD selected when the main word signal MWLB1 and the sub-word selection signals FXT2 and FXB2 are, activated, or denote the sub-word drivers SWD selected when the main word signal MWLB3 and the sub-word selection signals FXT3 and FXB3 are activated. When the sub-word drivers SWD denoted by the circles are selected, sub-word lines SWL10 to SWL13 or sub-word lines SWL30 to SWL33 are activated.

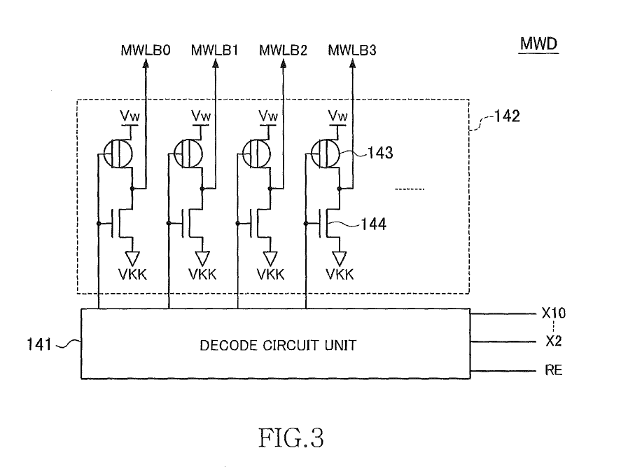

Turning to FIG. 3, the main word driver MWD includes a decode circuit unit 141 to which a part of address signals X10 to X2 and the row enable signal RE are input and a buffer circuit unit 142 that drives an output signal from the decode circuit unit 141. Each of drivers constituting the buffer circuit unit 142 is an inverter circuit configured by connecting a P-channel MOS transistor 143 and an N-channel MOS transistor 144 in series. A boost potential Vw is supplied to a source of the transistor 143 and a negative potential Vkk is supplied to a source of the transistor 144. With this configuration, when the output signal from the decode circuit unit 141 is activated at a high level, the main word signal MWLB at a Vkk level is output from the corresponding driver. On the other hand, when the output signal from the decode circuit unit 141 is deactivated at a low level, the main word signal MWLB at a Vw level is output from the corresponding driver.

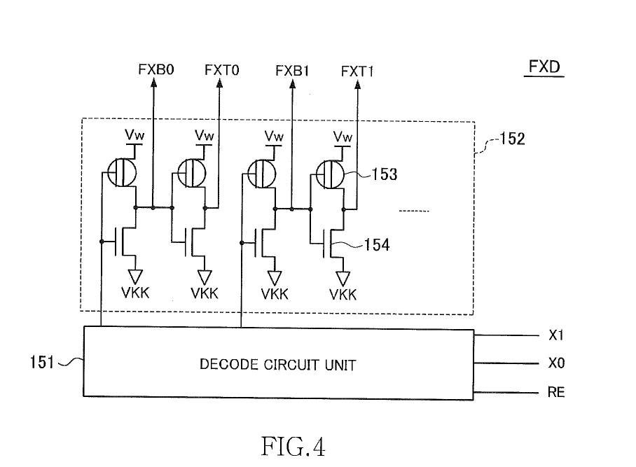

Turning to FIG. 4, the sub-word selection driver FXD includes a decode circuit unit 151 to which remaining address signals X1 and X0 and the row enable signal RE are input and a buffer circuit unit 152 that drives an output signal from the decode circuit unit 151. Each of drivers constituting the buffer circuit unit 152 has two stages of inverter circuits, each of which is configured by connecting a P-channel MOS transistor 153 and an N-channel MOS transistor 154 in series. The boost potential Vw is supplied to sources of the transistor 153 and the negative potential Vkk is supplied to sources of the transistor 154. With this configuration, when the output signal from the decode circuit unit 151 is activated at a high level, the sub-word selection signal FXT at a Vw level and the sub-word selection signal FXB at a Vkk level are output from the corresponding driver. On the other hand, when the output signal from the decode circuit unit 151 is deactivated at a low level, the sub-word selection signal FXT at the Vkk level and the sub-word selection signal FXB at the Vw level are output from the corresponding driver.

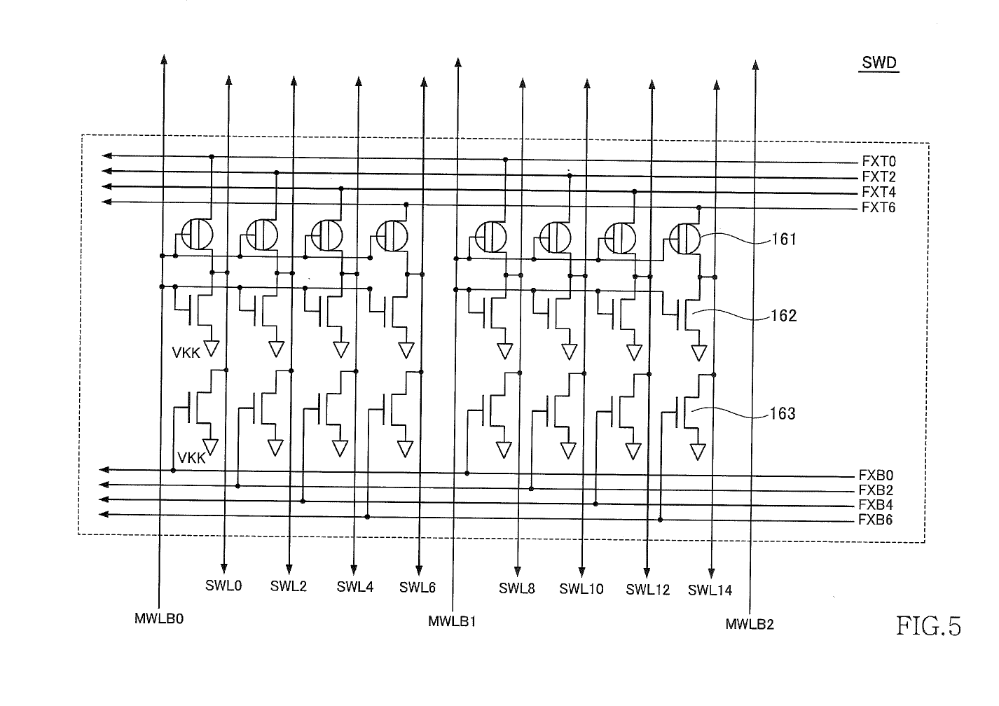

Turning to FIG. 5, the sub-word driver SWD includes inverter circuits each configured by connecting a P-channel MOS transistor 161 and an N-channel MOS transistor 162 in series. The corresponding sub-word selection signal FXT is supplied to a source of the transistor 161 and the negative potential Vkk is supplied to a source of the transistor 162. Furthermore, the corresponding main word signal MWLB is supplied to gate electrodes of these transistors 161 and 162. Drains of these transistors 161 and 162 are connected to the corresponding sub-word line SWL. Further, an N-channel MOS transistor 163 is connected between the sub-word line SWL and the negative potential Vkk and the corresponding sub-word selection signal FXB is supplied to a gate electrode of the transistor 163. With this configuration, when the main word signal MWLB is activated at a low level (a Vkk level) and the sub-word selection signal FXT is activated at a high level (a Vw level), the corresponding sub-word line SWL is driven to a high level (a Vw level). In other cases, the sub-word line SWL is driven to a low level (a Vkk level).

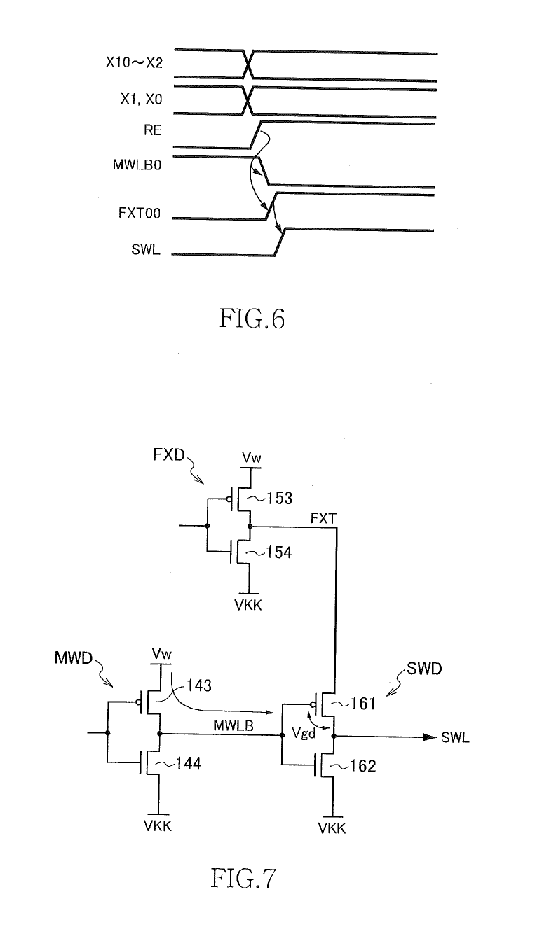

Turning to FIG. 6, when the address signals X10 to XO change, the row enable signal RE is activated after a predetermined time elapses. In response thereto, a predetermined main word signal MWLB (MWLB0 in FIG. 6) is activated at a low level and a predetermined sub-word selection signal FXT (FXT00 in FIG. 6) is activated at a high level. As a result, the corresponding sub-word driver SWD is activated and the corresponding sub-word line SWL is driven to a high level.

Turning to FIG. 7, when the main word signal MWLB is deactivated at a high level, a gate-drain voltage Vgd of the transistor 161 becomes a relatively high voltage of Vw-Vkk. Accordingly, a GIDL is generated in this period. Although the GIDL is not a serous problem at the time of general operations, the GIDL is a leak current that is not negligible in the operation mode such as a standby mode in which low current consumption is required. As described below in detail, the semiconductor device 100 according to the first embodiment can greatly reduce the GIDL generated in the transistor 161 in the standby mode.

Referring back to FIG. 1, the semiconductor device 100 according to the first embodiment includes a boost-potential generation circuit (a power supply circuit) 170 that generates the boost potential Vw. Two reference-potential generation circuits 181 and 182 supply reference potentials different from each other to the boost-potential generation circuit 170. The boost-potential generation circuit 170 selects one of the reference signals based on a standby signal STBY. The standby signal STBY is generated by an OR circuit 190 that receives the self-refresh signal MSRF and the precharge power-down signal PPDN.

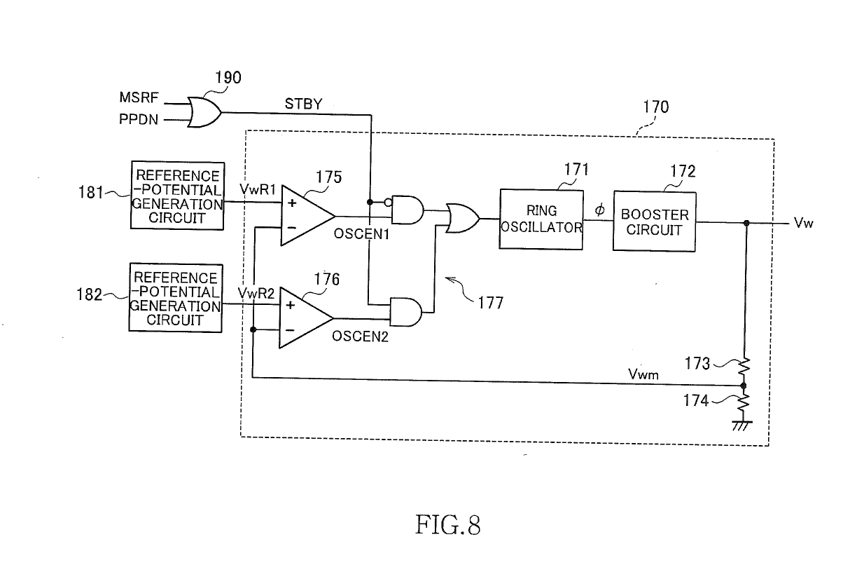

Turning to FIG. 8, the boost-potential generation circuit 170 includes a ring oscillator 171 that generates an oscillator signal ? and a booster circuit 172 that performs a boost operation in response to the oscillator signal ?. An output from the booster circuit 172 is used as the boost potential Vw. The boost potential Vw is divided by resistors 173 and 174, thereby generating a monitor potential Vwm. Comparators 175 and 176 compare the monitor potential Vwm with reference potentials VwR1 and VwR2, respectively. The reference potential VwR1 is a potential output from the reference-potential generation circuit 181, the reference potential VwR2 is a potential output from the reference-potential generation circuit 182, and a relation between the reference potentials VwR1 and VwR2 is expressed as follows.

VwR1>VwR2

These comparators 175 and 176 activate output signals OSCEN1 and OSCEN2 when the monitor potential Vwm is lower than the reference potentials VwR1 and VwR2, respectively.

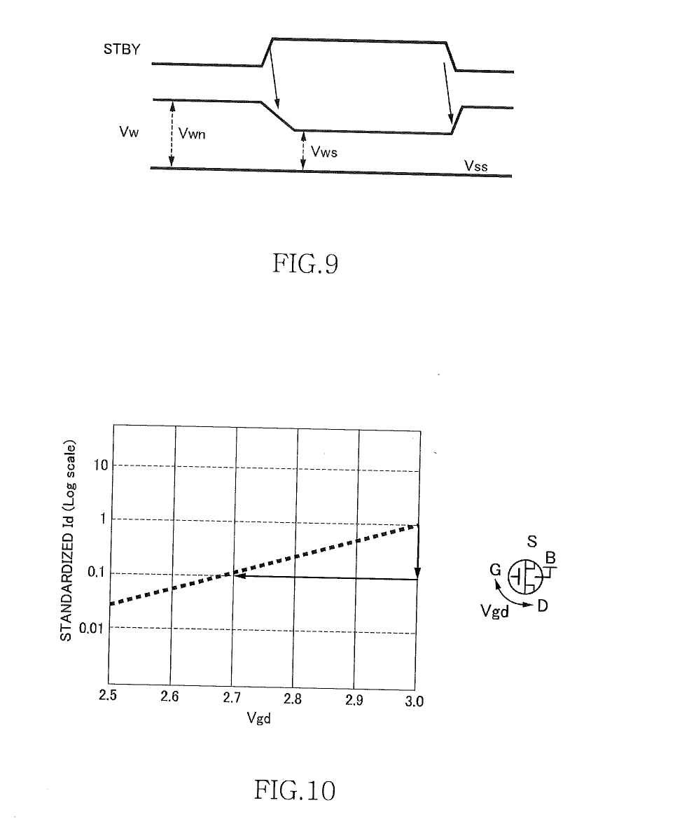

The output signals OSCEN1 and OSCEN2 from the comparators 175 and 176 are supplied to a logical gate circuit 177. The logical gate circuit 177 supplies one of the output signals OSCEN1 and OSCEN2 to the ring oscillator 171. Specifically, the logical gate circuit 177 selects the output signal OSCEN1 from the comparator 175 when the standby signal STBY is at a low level, that is, the operation mode is neither the self-refresh mode nor a precharge standby mode. The logical gate circuit 177 selects the output signal OSCEN2 from the comparator 176 when the standby signal STBY is at a high level, that is, the operation mode is the self-refresh mode or the precharge standby mode. The boost potential Vw thereby changes depending on the standby signal STBY as shown in FIG. 9. Specifically, when the standby signal STBY is deactivated at a low level, the level of the boost potential Vw is Vwn. When the standby signal STBY is activated at a high level, the level of the boost potential Vw is Vws (<Vwn).

Turning to FIG. 10, the GIDL increases exponentially in proportion to the gate-drain voltage Vgd. For example, when a current amount Id of the GIDL is 1 in a case where the gate-drain voltage Vgd is 3.0 V, the current amount Id of the GIDL is reduced to 0.1 when the gate-drain voltage Vgd is reduced to 2.7 V. Therefore, when the boost potential Vw is designed so that the boost potential Vw (=Vwn) at the time of the normal operation is 3.0 V and that the boost potential Vw (=Vws) at the time of the self-refresh mode or the precharge standby mode is 2.7 V, the GIDL generated in the self-refresh mode or the precharge standby mode can be reduced to one-tenth of a conventional GIDL. When the level of the boost potential Vw is lowered to Vws at the time of the self-refresh mode, a time required for the refresh operation possibly increases. However, this hardly causes any harm because a read operation or a write operation is not performed in the self-refresh mode.

As explained above, the semiconductor device 100 according to the first embodiment can greatly reduce the GIDL generated in the sub-word driver SWD at the time of the self-refresh mode or the precharge standby mode.

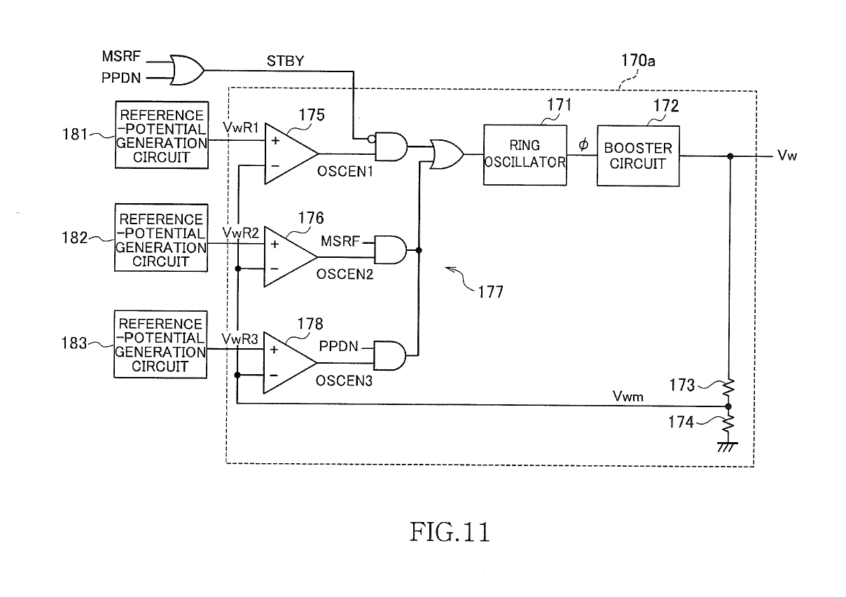

Turning to FIG. 11, the boost-potential generation circuit 170a is identical in circuit configuration to the boost-potential generation circuit 170 shown in FIG. 8 except for addition of a third comparator 178 and a circuit configuration of the logical gate circuit 177. The comparator 178 is a circuit that compares a reference potential VwR3 with the monitor potential Vwm, and the comparator 178 activates an output signal OSCEN3 when the monitor signal Vwm is lower than the reference potential VwR3. The reference potential VwR3 is a potential output from a reference-potential generation circuit 183, and a relation among the reference potentials VwR1, VwR2, and VwR3 is expressed as follows.

VwR1>VwR2>VwR3

The logical gate circuit 177 supplies one of the output signals OSCEN1, OSCEN2, and OSCEN3 to the ring oscillator 171 based on the standby signal STBY, the self-refresh signal MSRF, and the precharge power-down signal PPDN. Specifically, the logical gate circuit 177 selects the output signal OSCEN1 from the comparator 175 when the standby signal STBY is at a low level, that is, the operation mode is neither the self-refresh mode nor the precharge standby mode. The logical gate circuit 177 selects the output signal OSCEN2 from the comparator 176 when the self-refresh signal MSRF is at a high level, that is, the operation mode is the self-refresh mode. The logical gate circuit 177 selects the output signal OSCEN3 from the comparator 178 when the precharge power-down signal PPDN is at a high level, that is, the operation mode is the precharge standby mode.

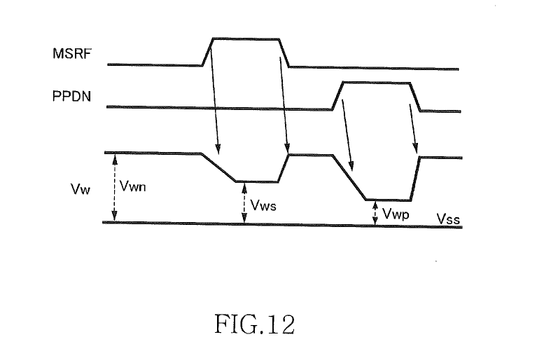

As shown in FIG. 12, the boost potential Vw thereby changes at three stages depending on the operation mode. Specifically, when the self-refresh signal MSRF is activated at a high level, the level of the boost potential Vw is Vws (<Vwn). When the precharge power-down signal PPDN is activated at a high level, the level of the boost potential Vw is Vwp (<Vws). In other cases, the level of the boost potential Vw is Vwn.

In this modification, the GIDL generated in the precharge standby mode can be further reduced. In addition, no problem occurs even if the level of the boost potential Vw is greatly reduced because the row access is not executed at all at the time of the precharge standby mode.

A second embodiment of the present invention is explained next.

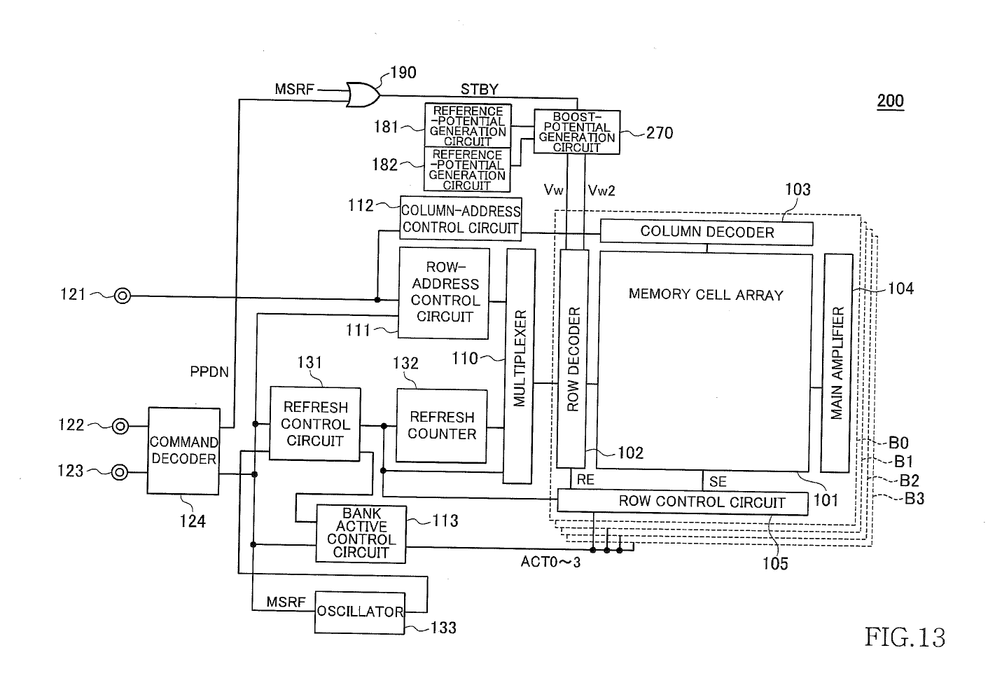

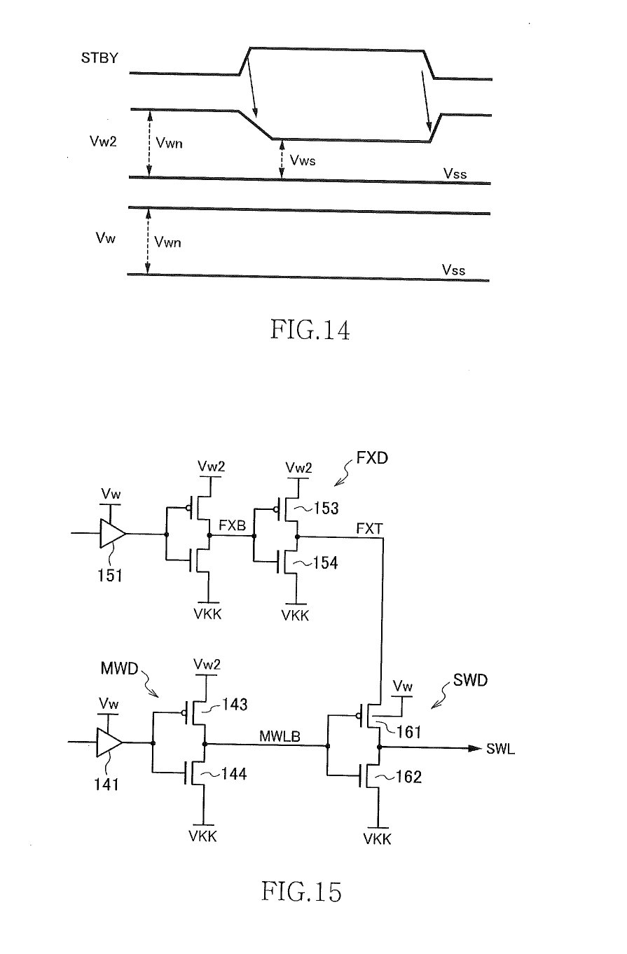

Turning to FIG. 13, the semiconductor device 200 according to the second embodiment differs from the semiconductor device 100 according to the first embodiment in that two types of boost potentials Vw and Vw2 are supplied to the row decoder 102 from a boost-potential generation circuit 270. The boost-potential generation circuit 270 generates the boost potential Vw based on a reference potential output from the reference-potential generation circuit 181, and generates the boost potential Vw2 based on a reference potential output from the reference-potential generation circuit 182. The boost-potential generation circuit 270 operates as shown in FIG. 14, that is, changes a level of the boost potential Vw2 in response to the standby signal STBY. Specifically, the level of the boost potential Vw2 is Vwn when the standby signal STBY is de-activated at a low level, and is Vws (<Vwn) when the standby signal STBY is activated at a high level. The level of the boost potential Vw is always Vwn irrespective of the standby signal STBY.

Turning to FIG. 15, the boost potential Vw2 is supplied to the sources of the transistors 143 and 153 whereas the boost potential Vw is supplied to other power supply nodes that need a boost potential. The other power supply nodes that need the boost potential Vw are sources of P-channel MOS transistors included in the decode circuit unit 141 shown in FIG. 3 and in the decode circuit unit 151 shown in FIG. 4 and a substrate of the transistor 161 shown in FIG. 5. That is, the semiconductor device 200 is characterized by using the boost potential Vw2 only for last stages supplying the boost potential to the sub-word driver SWD and using the boost potential Vw for the other power supply nodes.

With this configuration, parasitic capacities of power supply wirings for supplying the boost potential Vw2 can be made very small. Therefore, it is possible to quickly changes the level of the boost potential Vw2 depending on the standby signal STBY. This makes it possible to quickly return the level of the boost potential Vw2 from Vwp to Vwn at the time of returning to a normal operation mode from the standby state. In addition, similarly to the first embodiment, it is possible to reduce the current consumption at the time of the standby mode because the gate-drain voltage Vgd of the transistor 161 in which the GIDL is generated is lowered in the standby mode.

A third embodiment of the present invention is explained next.

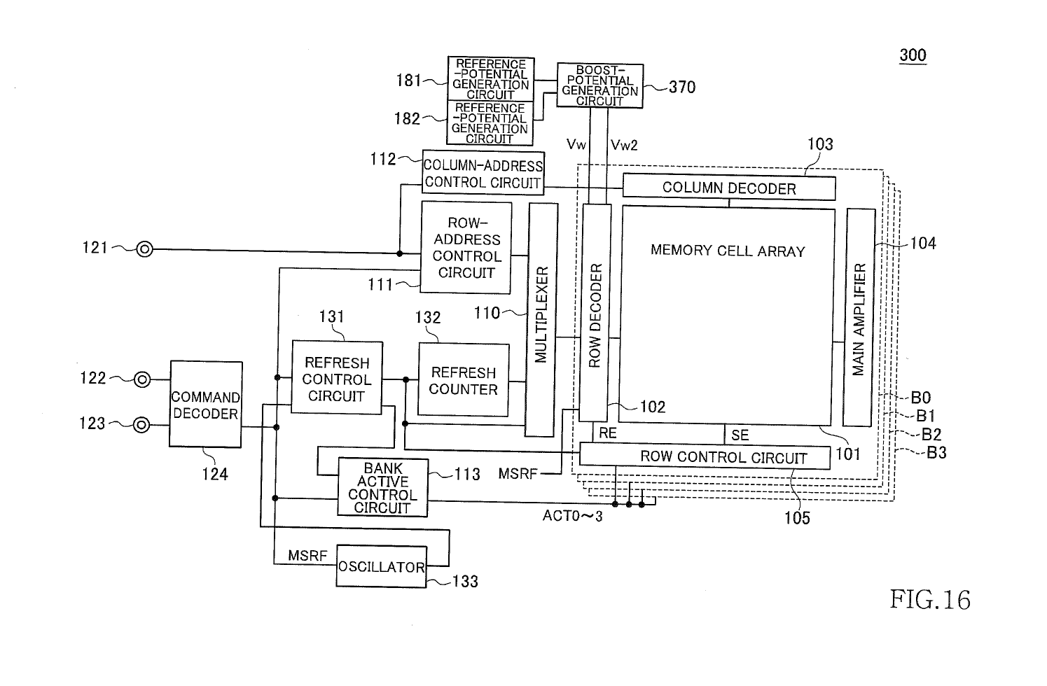

Turning to FIG. 16, the semiconductor device 300 according to the third embodiment differs from the semiconductor device 200 according to the second embodiment shown in FIG. 13 in that the self-refresh signal MSRF is supplied to the row decoder 102. Furthermore, the two types of boost potentials Vw and Vw2 are supplied to the row decoder 102 from a boost-potential generation circuit 370, and the levels of the boost potentials Vw and Vw2 are always set to Vwn and Vws (<Vwn), respectively. The boost potential Vw2 is a potential used in the main word drivers MWD and the boost potential Vw is used in the sub-word selection drivers FXD.

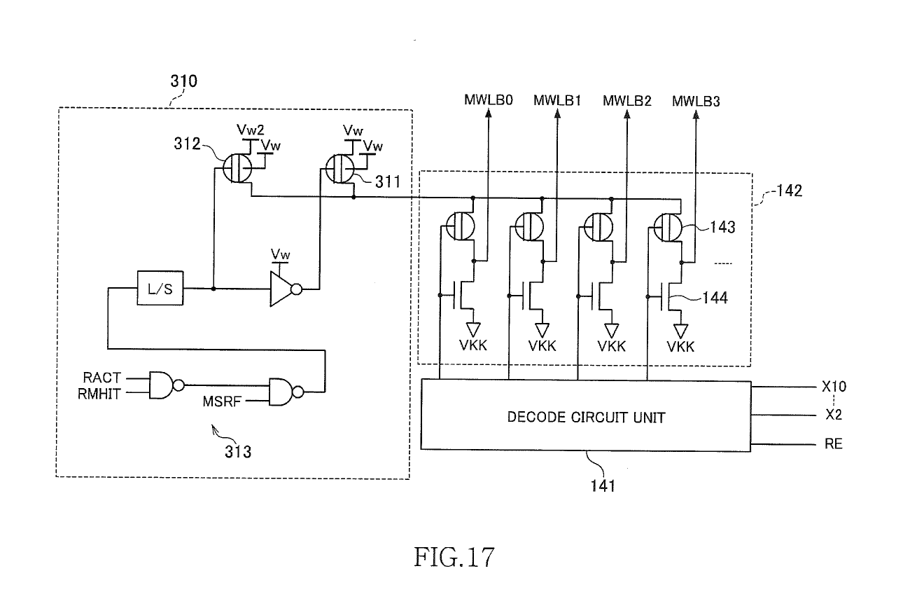

Turning to FIG. 17, the switching circuit 310 includes a transistor 311 that supplies the boost potential Vw (=Vwn) to the buffer circuit unit 142 and a transistor 312 that supplies the boost potential Vw2 (=Vws) to the buffer circuit unit 142, and a logical gate circuit 313 turns on the transistor 311 or 312. An active signal RACT, the self-refresh signal MSRF, and a hit signal RMHIT are supplied to the logical gate circuit 313, and the logical gate circuit 313 supplies a signal obtained by performing a logical operation on these signals RACT, MSRF, and RMHIT to the transistors 311 and 312 via a level shift circuit L/S. The active signal RACT is a signal activated at a high level at the time of executing the row access, and the self-refresh signal MSRF is a signal activated at a high level at the time of the self-refresh mode. The hit signal RMHIT is a signal activated at a high level when a combination of the main word signal MWLB and the sub-word selection signal FX that correspond to each other and that are respectively deactivated and activated is present. The hit signal RMHIT is a signal that is unnecessary when one switching circuit 310 is used commonly to the buffer circuit 142; however, it is necessary when drivers included in the buffer circuit unit 142 are divided into groups and the switching circuit 310 is individually allocated to each of the groups.

With this configuration, at the time of a normal operation at which the self-refresh signal MSRF is at a low level, the transistor 311 is selected, so that the boost potential Vw (=Vwn) is supplied to the buffer circuit unit 142 as the source potential. At the time of the self-refresh mode at which the self-refresh signal MSRF is at a high level, the transistor 312 is basically selected, so that the boost potential Vw2 (=Vws) is supplied to the buffer circuit unit 142 as the source potential. However, even at the time of the self-refresh mode, when both the active signal RACT and the hit signal RMHIT are activated at a high level, then the transistor 311 is temporarily selected, and the source potential of the buffer circuit unit 142 temporarily returns to the boost potential Vw (=Vwn).

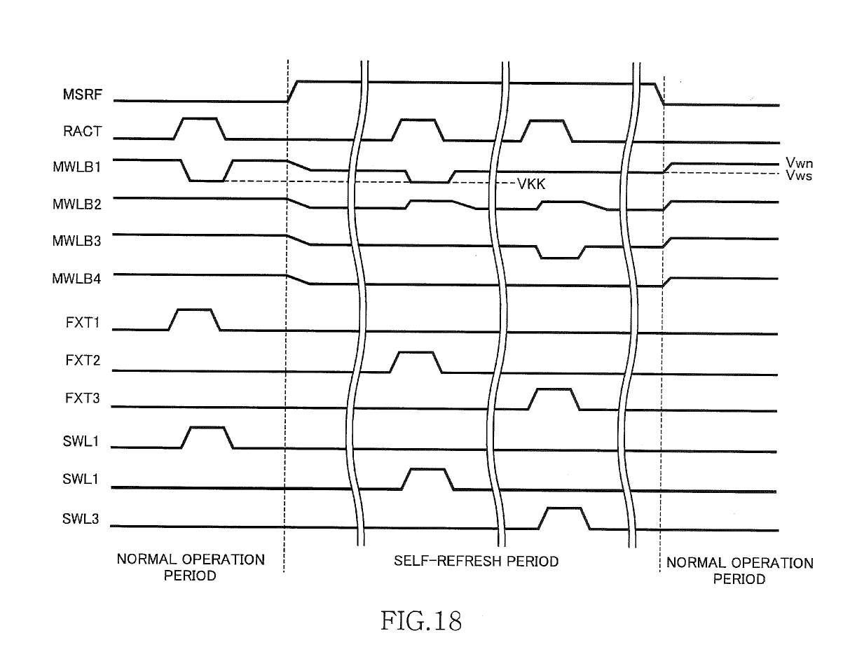

Turning to FIG. 18, at the time of a normal operation at which the self-refresh signal MSRF is at a low level, inactive levels of the main word signals MWLB (MWLB1 to MWLB4) are the boost potential Vw (=Vwn), and only the activated main word signal MWLB changes to a Vkk level. On the other hand, at the time of the self-refresh mode at which the self-refresh signal MSRF is at a high level, the inactive levels of the main word signals MWLB are lowered to the boost potential Vw2 (=Vws). When the oscillator 133 activates the active signal RACT, the selected main word signal MWLB (MWLB1, for example) changes to the Vkk level. At this time, the inactive level of the other main word signal MWLB (MWLB2, for example) allocated to the activated sub-word selection signal FX (FXT2, for example) temporarily returns to Vw (=Vwn) in response to the activation of the hit signal RMHIT.

This is because the activated sub-word selection signal FXT2 is allocated to the memory mat array RMAT2 to which the main word signal MWLB2 is allocated, as described with reference to FIG. 2. Therefore, when the main word signal MWLB2 is deactivated and the sub-word selection signal FXT2 is activated, the hit signal RMHIT corresponding to the main word signal MWLB2 is activated. The inactive level of the main word signal MWLB2 thereby temporarily returns to Vw (=Vwn).

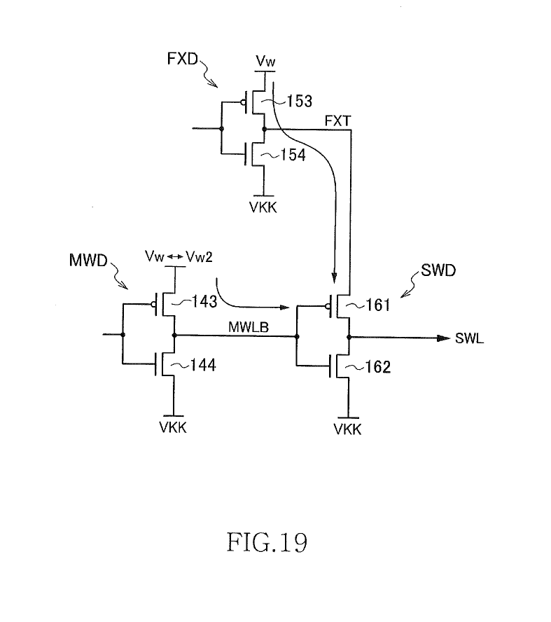

The reason for the need of the control described above is as follows. As shown in FIG. 19, when only the inactive level of the main word signal MWLB is lowered to Vw2 (=Vws) in a case where the main word signal MWLB is deactivated and the sub-word selection signal FXT is activated, then a potential difference is generated between a gate and the source of the transistor 161, and the leak current GIDL is generated. According to the third embodiment, to prevent the generation of such a leak current GIDL, the inactive level of the main word signal MWLB is returned to Vw (=Vwn). Because the levels of other deactivated main word signals MWLB are set to Vw2 (=Vws), it is possible to greatly reduce the GIDL generated in the transistor 161.

In this way, according to the third embodiment, similarly to the above embodiments, it is possible to greatly reduce the GIDL at the time of the self-refresh mode.

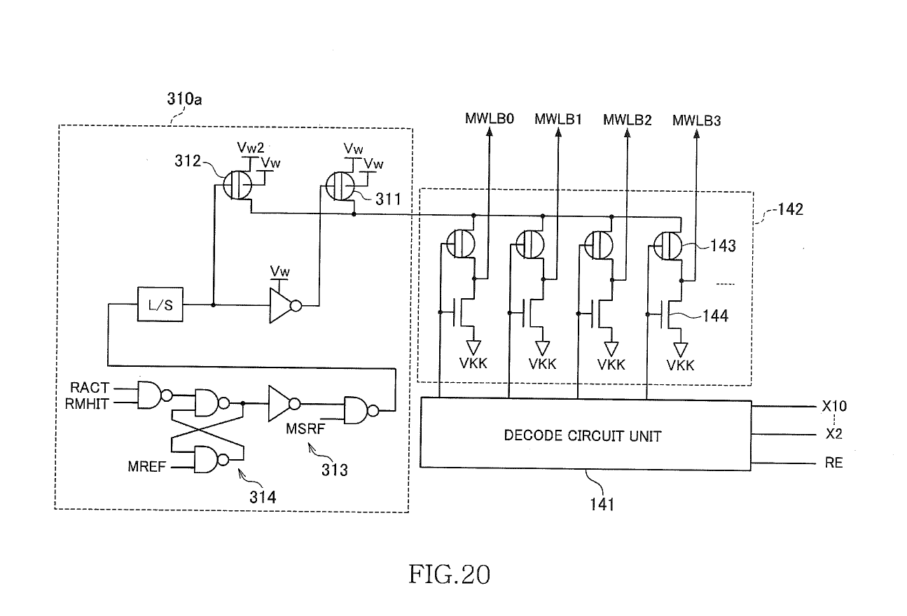

Turning to FIG. 20, the switching circuit 310a differs from the switching circuit 310 shown in FIG. 17 in that the logical gate circuit 313 includes an SR latch circuit 314. The SR latch circuit 314 is set when both the active signal RACT and the hit signal RMHIT are activated at a high level, and is reset when a refresh state signal MREF is deactivated at a low level. The refresh state signal MREF is a signal activated at a high level in a period of performing a refresh operation, and the active signal RACT is activated at plural times in the period in which the refresh state signal MREF is at a high level.

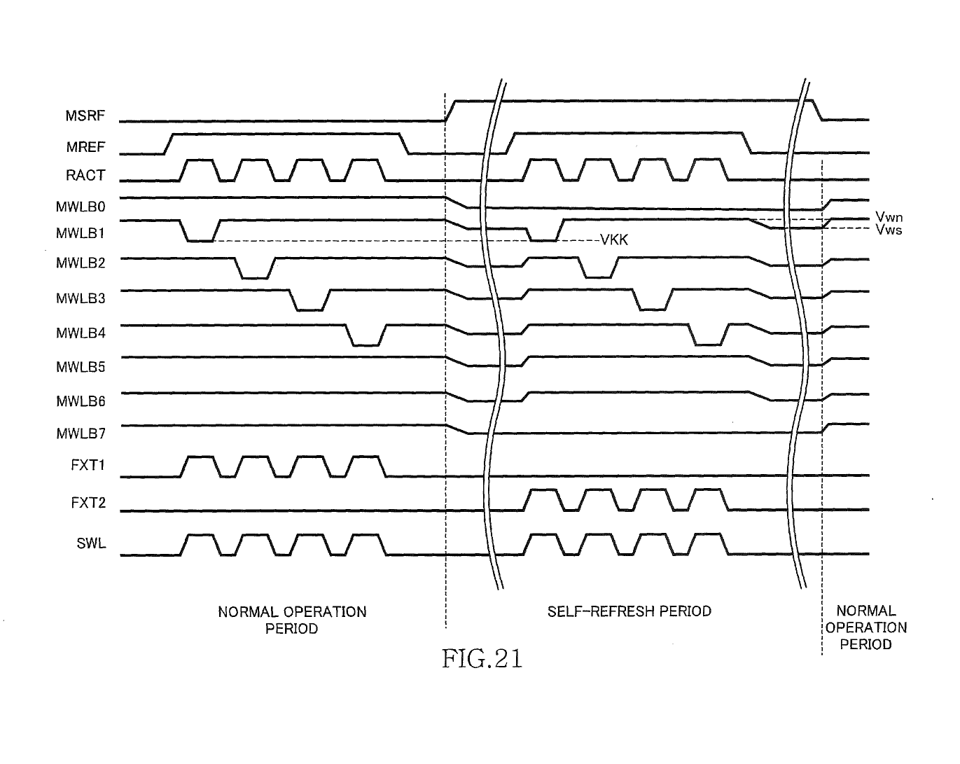

Turning to FIG. 21, when the auto-refresh command is issued at the time of a normal operation, then the refresh state signal MREF is activated at a high level, and the active signal RACT is activated at plural times in the period in which the refresh state signal MREF is at a high level. Predetermined sub-word lines SWL are thereby sequentially activated. Meanwhile, at the time of the self-refresh mode, the refresh state signal MREF is activated periodically. Furthermore, similarly to the above example, the inactive level of the inactive main word signal MWLB allocated to the activated sub-word selection signal FX (FXT2, for example) returns to Vw (=Vwn) in response to the activation of the hit signal RMHIT. This state is maintained until the refresh state signal MREF becomes a low level. Accordingly, the level of the main word signal MWLB is not changed repeatedly from the boost potential Vw (=Vwn) to the boost potential Vw2 (=Vws). Therefore, it is possible to reduce a charge-discharge current accompanying switching of the boost potential.

It is apparent that the present invention is not limited to the above embodiments, but may be modified and changed without departing from the scope and spirit of the invention.

1. A semiconductor device comprising:
a memory cell array including a plurality of sub-word lines, a plurality of bit lines and a plurality of memory cells arranged at intersections of the sub-word lines and the bit lines;
a plurality of sub-word drivers each drives an associated one of the sub-word lines; and
a plurality of main word drivers each supplies a main word signal having one of a selected-level potential and an unselected-level potential to an associated one of the sub-word drivers,
wherein each of the sub-word drivers drives the associated one of the sub-word lines to an active level when an associated one of the main word signals has the selected-level potential, and drives the associated one of the sub-word lines to an inactive level when the associated one of the main word signals has the unselected-level potential, and wherein the unselected-level potential of the main word signals is variable depending on an operation mode.

2. The semiconductor device as claimed in claim 1, wherein the un-selected-level potential of the main word signals is a first potential in a normal operation mode, and is a second potential that is lower than the first potential in a standby mode.

3. The semiconductor device as claimed in claim 1, wherein each of the sub-word drivers includes a P-channel MOS transistor and an N-channel MOS transistor that are connected in series, and each of the main word signals is supplied in common to gate electrodes of the P-channel MOS transistor and the N-channel MOS transistor of the associated one of the sub-word drivers.

4. The semiconductor device as claimed in claim 3, further comprising a plurality of sub-word selection drivers each supplies a sub-word selection signal having one of an active-level potential and an inactive-level potential to a source of the P-channel MOS transistor of an associated one of the sub-word drivers,
wherein the active-level potential of the sub-word selection signals is variable depending on the operation mode.

5. The semiconductor device as claimed in claim 3, further comprising a plurality of sub-word selection drivers each supplies a sub-word selection signal having one of an active-level potential and an inactive-level potential to a source of the P-channel MOS transistor of an associated one of the sub-word drivers,
wherein the unselected-level potential of each of the main word signals is variable depending on an associated one of the sub-word selection signals.

6. A semiconductor device comprising:
a sub-word selection driver generating a sub-word selection signal having one of an active-level potential and an inactive-level potential based on an address signal;
a main word driver generating a main word signal having one of a selected-level potential and an unselected-level potential based on the address signal;
a sub-word driver activates a sub-word line when the sub-word selection signal has the active-level potential and the main word signal has the selected-level potential; and
a power-supply circuit that generates the unselected-level potential by selecting one of a plurality of potentials including at least first and second potentials based on a control signal.

7. The semiconductor device as claimed in claim 6, wherein
the sub-word driver includes a P-channel MOS transistor and an N-channel MOS transistor that are connected in series,
the sub-word selection signal is supplied to a source of the P-channel MOS transistor, and
the main word signal is supplied in common to gate electrodes of the P-channel MOS transistor and the N-channel MOS transistor.

8. The semiconductor device as claimed in claim 7, wherein the un-selected-level potential is substantially equal to the active-level potential.

9. The semiconductor device as claimed in claim 8, wherein the P-channel MOS transistor has a body supplied with the unselected-level potential.

10. The semiconductor device as claimed in claim 8, wherein the P-channel MOS transistor has a body supplied with a body potential that is substantially constant irrespective of the control signal.

11. The semiconductor device as claimed in claim 7, wherein the active-level potential is substantially constant irrespective of the control signal.

12. A semiconductor device comprising:
a first decoder that generates a first selection signal by decoding a first part of an address signal;
a second decoder that generates a second selection signal by decoding a second part of the address signal;
a sub-word selection driver that includes first and second transistors connected in series, the first selection signal being supplied to gate electrodes of the first and second transistors;
a main word driver that includes third and fourth transistors connected in series, the second selection signal being supplied to gate electrodes of the third and fourth transistors;
a sub-word driver that includes fifth and sixth transistors connected in series, drains of the fifth and sixth transistors being connected to a sub-word line, a source of the fifth transistor being connected to drains of the first and second transistors, gate electrodes of the fifth and sixth transistors being connected to drains of the third and fourth transistors; and
a power-supply circuit that supplies a first potential to sources of the first and third transistors in a first operation mode, and supplies a second potential that is lower than the first potential to the source of the third transistor in a second operation mode.

13. The semiconductor device as claimed in claim 12, wherein the power-supply circuit supplies the second potential to the sources of the first and third transistors in the second operation mode.

14. The semiconductor device as claimed in claim 12, wherein, in the second operation mode, the power-supply circuit supplies the first potential to the source of the first transistor and supplies the second potential to the source of the third transistor.

15. The semiconductor device as claimed in claim 14, wherein the power-supply circuit temporarily changes a potential supplied to the source of the third transistor from the second potential to the first potential in response to an activation of the first selection signal in the second operation mode.

16. The semiconductor device as claimed in claim 12, wherein the first, third, and fifth transistors are P-channel MOS transistors, and the second, fourth, and sixth transistors are N-channel MOS transistors.
